(19) United States
(12) Patent Application Publication
(10) Pub. No.: US 2014/0096806 A1
(43) Pub. Date: Apr. 10, 2014

(54) PRIVATE ELECTRIC GENERATOR

(71) Applicant: Electronics and Telecommunications Research Institute, Daejeon (KR)

(72) Inventors: Hoon JEONG, Daejeon (KR); Chang Won Lee, Gyeonggi-do (KR); Gwan Joong Kim, Daejeon (KR)

(21) Appl. No.: 13/942,811

(22) Filed: Jul. 16, 2013

(30) Foreign Application Priority Data
Oct. 5, 2012 (KR) 10-2012-0110588

(51) Int. Cl. H01L 35/32

(52) U.S. Cl. CPC H01L 35/32
USPC 136/205

(57) ABSTRACT

Provided is a private electric generator including: a first heat absorbing panel that absorbs heat corresponding to temperature; a second heat absorbing panel that absorbs heat corresponding to ground temperature or water temperature; and a thermoelectric generator that is disposed between the first and second heat absorbing panels and uses a temperature difference in the heat absorbed in the first and second heat absorbing panels to generate power, thereby generating power based on a difference in temperature and ground temperature or water temperature according to a daily temperature range.

### CROSS-REFERENCE TO RELATED APPLICATIONS

This application claims priority to and the benefit of Korean Patent Application No. 10-2012-0110588 filed in the Korean Intellectual Property Office on Oct. 5, 2012, the entire contents of which are incorporated herein by reference.

### TECHNICAL FIELD

An exemplary embodiment relates to a private electric generator, and more particularly, to a private electric generator generating power based on a difference in temperature and ground temperature or water temperature according to a daily temperature range.

### BACKGROUND ART

An exemplary embodiment is directed to a private electric generator generating power based on a difference in temperature and ground temperature or water temperature according to a daily temperature range to generate power for operating sensor nodes in the outdoor environment.

An exemplary embodiment provides a private electric generator, including: a first heat absorbing panel that absorbs heat corresponding to a temperature; a second heat absorbing panel that absorbs heat corresponding to a ground temperature or a water temperature; and a thermoelectric generator that is disposed between the first and second heat absorbing panels and uses a temperature difference in the heat absorbed in the first and second heat absorbing panels to generate power.

Another exemplary embodiment provides a private electric generator, including: a barrier curtain that shields an external heat source; a third heat absorbing panel that is disposed to be spaced under the barrier curtain and absorbs heat corresponding to a temperature below the barrier curtain; a fourth heat absorbing panel that absorbs heat corresponding to a ground temperature or a water temperature; and a thermoelectric generator that is disposed between the third and fourth heat absorbing panels and uses a temperature difference in the heat absorbed in the third and fourth heat absorbing panels to generate power.

### SUMMARY OF THE INVENTION

According to the exemplary embodiments of the present invention, the private electric generator can use the temperature difference between a temperature and a ground temperature or a water temperature, which can be used even in the regions where seasons are changed, to perform the private electric generation for operating the sensor nodes in the outdoor environment of both the season in which the temperature is higher than the water temperature and the season in which the temperature is lower than the water temperature.

According to the exemplary embodiments of the present invention, the private electric generator can use the temperature difference between temperature and ground temperature or water temperature, not directly using sunlight and thus can be used even in the place where sunlight is not directly reached.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a private electric generator according to a first exemplary embodiment of the present invention.

FIG. 2 is a cross-sectional view illustrating a private electric generator according to a second exemplary embodiment of the present invention.

FIG. 3 is a cross-sectional view illustrating a private electric generator according to a third exemplary embodiment of the present invention.

FIGS. 4 to 6 are graphs illustrating temperature and water temperature at which the private electric generators according to the first to third exemplary embodiments of the present invention are used.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

In describing components of embodiments, components of the same name may be denoted by different reference numerals in the accompanying drawings and may be denoted by the same reference numerals in spite of different drawings. However, even in this case, it does not mean that the corresponding components may have different functions according to embodiments or the same functions in different embodiments and the function of each component should be determined based on the description of each component in the corresponding embodiment.

In describing exemplary embodiments of the present invention, well-known functions or constructions will not be described in detail since they may unnecessarily obscure the understanding of the present invention.

In describing components of the present specification, terms such as first, second, A, B, (a), (b), etc. may be used. These terms are used only to differentiate the components from other components. Therefore, the nature, sequence or order, etc. of the corresponding components are not limited by these terms. When any components are “connected”, “coupled”, or “linked” to other components, it is to be noted that the components may be directly connected or linked to other components, but the components may be “connected”, “coupled”, or “linked” to other components via another component therebetween.

Hereinafter, portions required to understand an operation and an action of a private electric generator according to exemplary embodiments of the present invention will be described in detail with reference to the accompanying drawings.

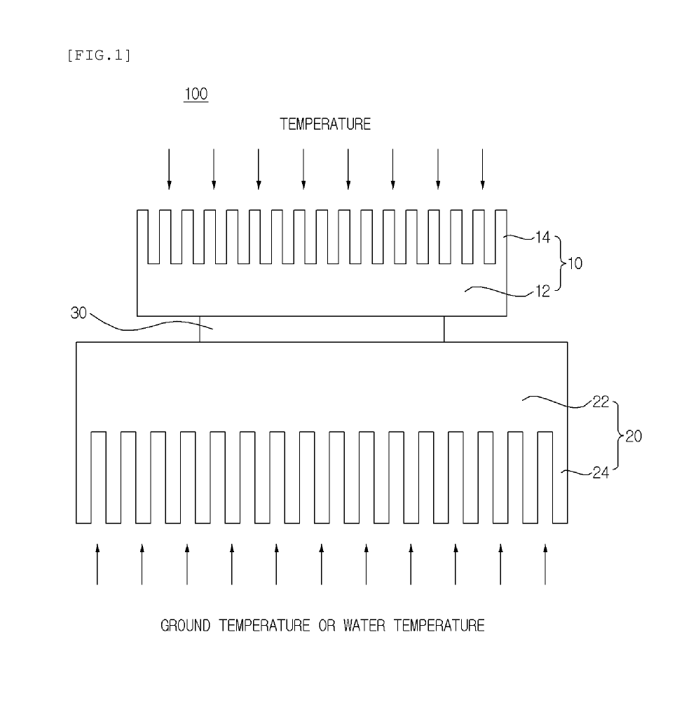

FIG. 1 is a cross-sectional view illustrating a private electric generator according to a first exemplary embodiment of the present invention.

Referring to FIG. 1, a private electric generator 100 includes a first heat absorbing panel 10, a second heat absorbing panel 20, and a thermoelectric generator 30 that generates power between the first and second heat absorbing panels 10 and 20.

Herein, the first heat absorbing panel 10 may be exposed to the atmosphere in the outdoor environment to absorb heat corresponding to the temperature of the atmosphere.

That is, the first heat absorbing panel 10 may absorb light emitted from an external heat source such as the sun, and the like, or reabsorb heat absorbed in the air by the light.

The first heat absorbing panel 10 may include a first main absorbing panel 12 and at least one first sub-absorbing protrusion 14 that protrudes to the outside from the first main absorbing panel 12.

Herein, the first main absorbing panel 12 may collect heat absorbed in the at least one first sub-absorbing protrusion 14 and the first sub-absorbing protrusion 14 may protrude from the first main absorbing panel 12 so as to expand an area contacting the atmosphere, thereby absorbing heat.

The second heat absorbing panel 20 is disposed on the ground or in water such as stream, sea, and river to absorb heat corresponding to a ground temperature or a water temperature.

The second heat absorbing panel 20 may include a second main absorbing panel 22 and at least one second sub-absorbing protrusion 24 that protrudes to the ground or water from the second main absorbing panel 22.

Herein, the second main absorbing panel 22 may collect heat absorbed in the at least one second sub-absorbing protrusion 24 and the second sub-absorbing protrusion 24 may protrude from the second main absorbing panel 22 so as to expand an area contacting the atmosphere, thereby absorbing heat.

The first and second heat absorbing panels 10 and 20 may be a heat sink and may be made of materials capable of absorbing heat in addition to the heat sink, but are not limited thereto.

The thermoelectric generator 30 is disposed between the first and second heat absorbing panels 10 and 20 and may generate power when the temperature difference of the heat absorbed between the first and second heat absorbing panels 10 and 20 ranges from 5° C. to 20° C.

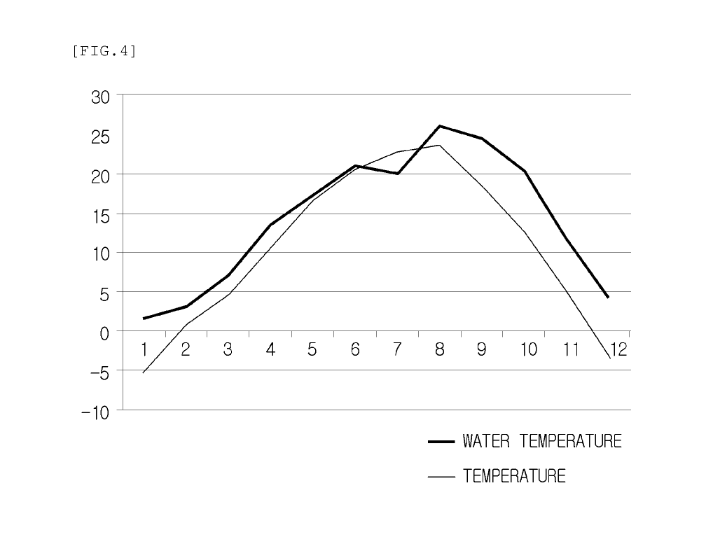

Herein, the exemplary embodiments of the present invention will be described with reference to FIGS. 4 to 6.

FIG. 4 is a graph illustrating average water temperature and temperature every month (season) a year in medium and small rivers.

That is, as illustrated in FIG. 4, the temperature difference between average temperature and water temperature every month is generated and it can be appreciated that the temperature difference generally in January and February and from August to December ranges from 5° C. to 20° C. in which the thermoelectric generator 30 may generate power.

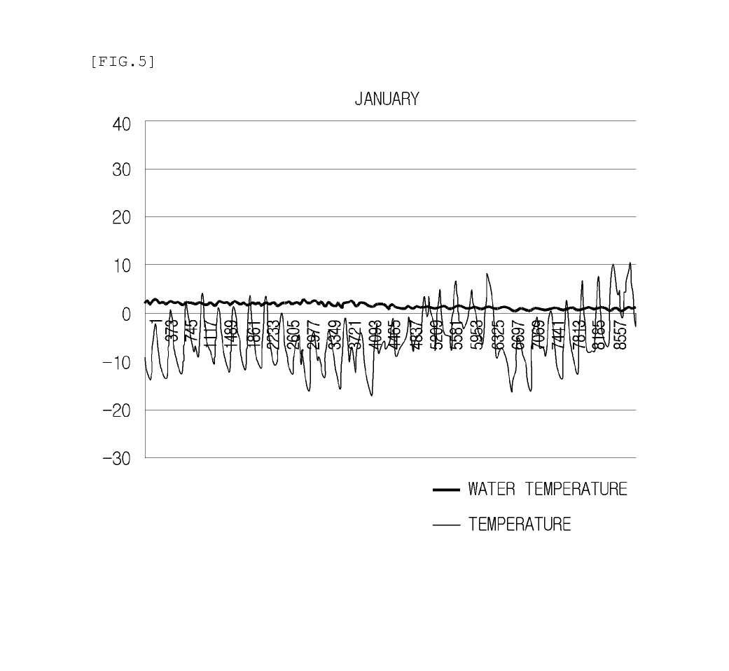

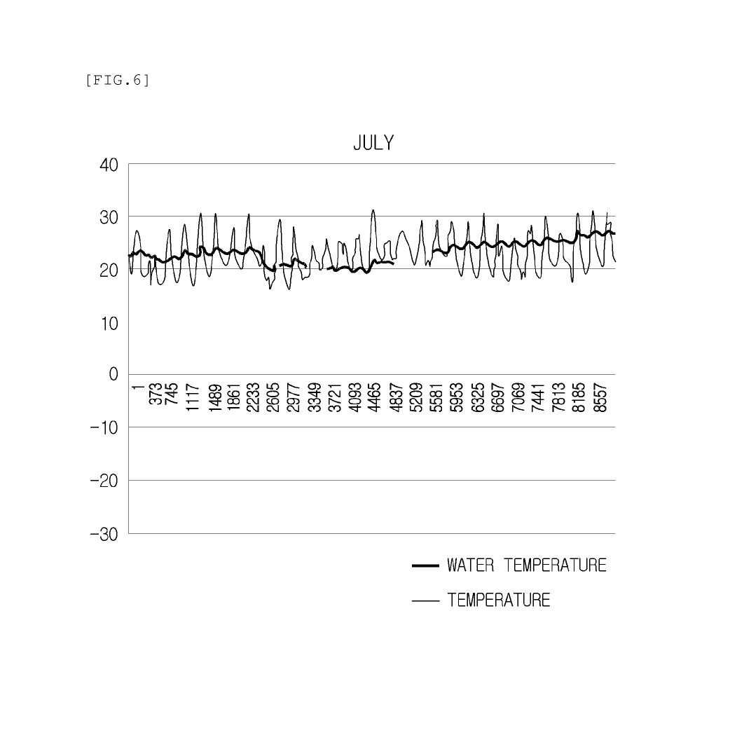

FIG. 5 is a graph illustrating the water temperature and the temperature of January illustrated in FIG. 4 and FIG. 6 is a graph illustrating the water temperature and the temperature of July illustrated in FIG. 4.

That is, as illustrated in FIGS. 5 and 6, it can be appreciated that temperature difference between the water temperature and temperature in January and July ranges from 5° C. to 20° C. in which the thermoelectric generator 30 may generate power.

As illustrated in FIG. 5, it can be appreciated that in January (winter), the water temperature is constant, which barely shows daily temperature range, while the temperature has a large daily temperature range.

As illustrated in FIG. 6, it can be appreciated that the water temperature and the temperature in July (summer) show a result opposite to January of FIG. 5.

That is, the thermoelectric generator 30 may generate power by the temperature difference between the water temperature and the temperature in January and July, that is, in winter and summer.

The private electric generator 100 according to the first exemplary embodiment of the present invention may be used in a region in which temperature is relatively higher than water temperature.

That is, the private electric generator 100 may be used in an equatorial region, that is, a region in which temperature is always higher than water temperature throughout the year, to generate power throughout the year.

The private electric generator 100 may include a charging device (not illustrate) that charges and stores power generated from the thermoelectric generator 30.

That is, the charging device may be a battery and may supply the charged and stored power when the temperature difference between temperature and water temperature is not generated.

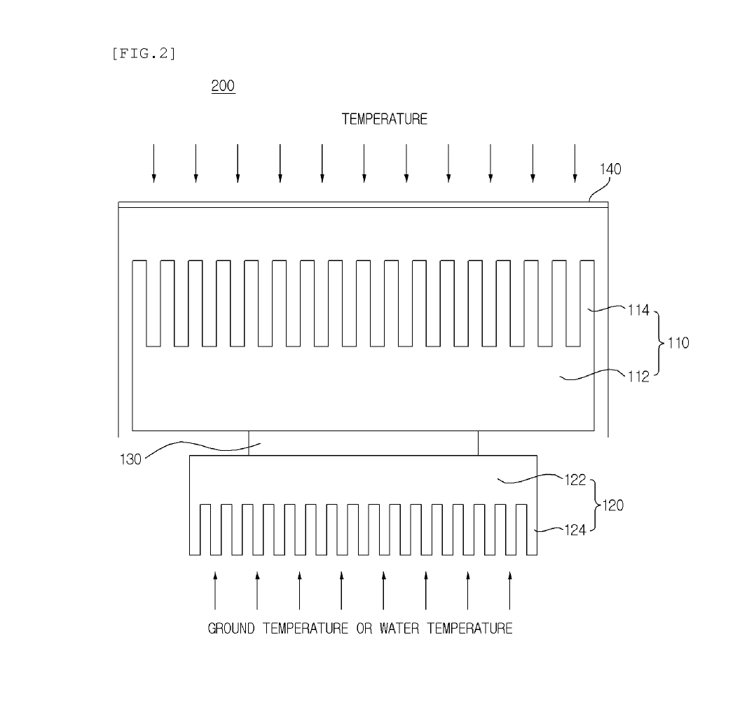

FIG. 2 is a cross-sectional view illustrating a private electric generator according to a second exemplary embodiment of the present invention.

Referring to FIG. 2, a private electric generator 200 may include a first heat absorbing panel 110, a second heat absorbing panel 120, a thermoelectric generator 130, and a barrier curtain 140.

Herein, the first heat absorbing panel 110 may be exposed to the atmosphere in the outdoor environment to absorb heat corresponding to the temperature of the atmosphere.

That is, the first heat absorbing panel 110 may absorb light emitted from an external heat source such as the sun, and the like, or reabsorb heat absorbed in the air by the light.

The first heat absorbing panel 110 may include a first main absorbing panel 112 and at least one first sub-absorbing protrusion 114 that protrudes to the outside from the first main absorbing panel 112.

Herein, the first main absorbing panel 112 may collect heat absorbed in the at least one first sub-absorbing protrusion 114 and the first sub-absorbing protrusion 114 may protrude from the first main absorbing panel 112 so as to expand an area contacting the atmosphere, thereby absorbing heat.

The second heat absorbing panel 120 is disposed on the ground or in water such as stream, sea, and river to absorb heat corresponding to ground temperature or water temperature.

The second heat absorbing panel 120 may include a second main absorbing panel 122 and at least one second sub-absorbing protrusion 124 that protrudes to the ground or water from the second main absorbing panel 122.

Herein, the second main absorbing panel 122 may collect heat absorbed in the at least one second sub-absorbing protrusion 124 and the second sub-absorbing protrusion 124 may protrude from the second main absorbing panel 122 so as to expand an area contacting the atmosphere, thereby absorbing heat.

The first and second heat absorbing panels 110 and 120 may be a heat sink and may be made of materials capable of absorbing heat in addition to the heat sink, but are not limited thereto.

A size of the first heat absorbing panel 110 may be one to four times as large as that of the second heat absorbing panel 120.

The thermoelectric generator 130 is disposed between the first and second heat absorbing panels 110 and 120 and may generate power when the temperature difference of the heat absorbed between the first and second heat absorbing panels 110 and 120 ranges from 5° C. to 20° C.

Herein, referring to FIGS. 4 and 6, the barrier curtain 140 shielding the external heat source may be installed on the first heat absorbing panel 110 heated by the external heat source so that the private electric generator 200 may be used in a region where water temperature is higher than temperature.

That is, the barrier curtain 140 prevents the first heat absorbing panel 110 from being heated by the external heat source so that the temperature difference due to the heat absorbed in the second heat absorbing panel 120 may be controlled so as to range from 5° C. to 25° C. in which the thermoelectric generator 130 may generate power.

The private electric generator 200 illustrated in FIG. 2 may be used in regions relatively opposite to the regions where the private electric generator 100 illustrated in FIG. 1 is used, that is, regions such as polar regions.

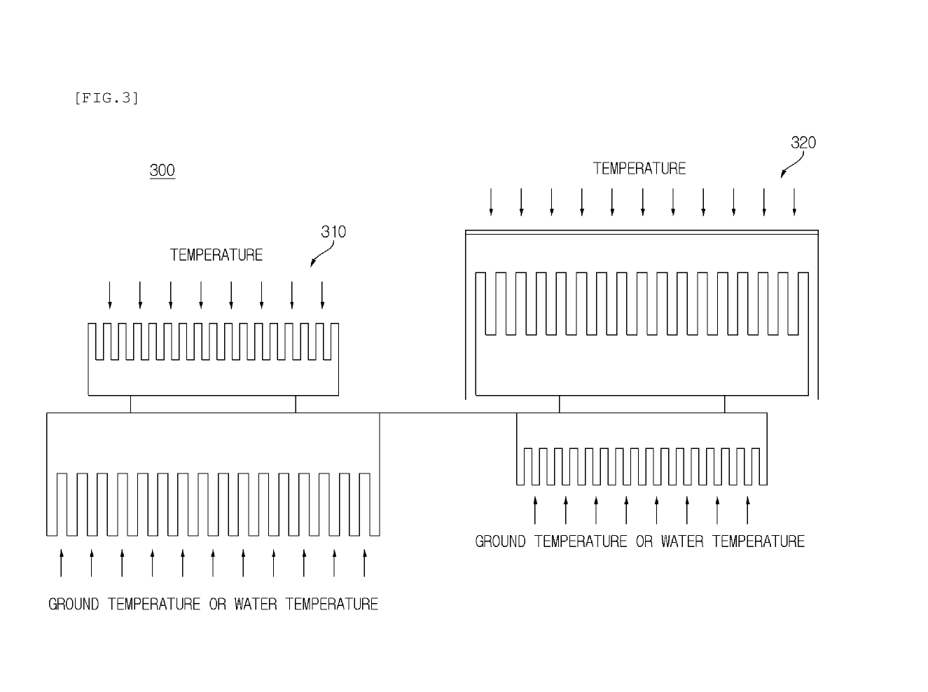

FIG. 3 is a cross-sectional view illustrating a private electric generator according to a third exemplary embodiment of the present invention.

A private electric generator 300 illustrated in FIG. 3 corresponds to the case in which both the private electric generators 100 and 200 illustrated in FIGS. 1 and 2 are applied.

That is, the private electric generator 300 may include a first private electric generator 310 and a second private electric generator 320.

The first private electric generator 310 has the same structure as the private electric generator 100 illustrated in FIG. 1 and may generate power when temperature during the summer season is higher than water temperature and the second private electric generator 320 has the same structure as the private electric generator 200 illustrated in FIG. 2 and may generate power when water temperature during the winter season is higher than temperature.

That is, the private electric generator 300 may be used a region with summer and winter seasons like Korea, which may provide convenience for a user.

Although the preferred embodiments of the present invention are described in detail, the present invention may be variously modified and changed by a person with ordinary skill in the art to which the present invention pertains without departing from the spirit and scope of the present invention defined in the art to which the present invention pertains. Therefore, the change of the following embodiments of the present invention cannot deviate from the technology of the present invention.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. A private electric generator, comprising:
a first heat absorbing panel that absorbs heat corresponding to temperature;
a second heat absorbing panel that absorbs heat corresponding to ground temperature or water temperature; and
a thermoelectric generator that is disposed between the first and second heat absorbing panels and uses a temperature difference in the heat absorbed in the first and second heat absorbing panels to generate power.

2. The private electric generator of claim 1, further comprising:
a charging device that stores the power generated from the thermoelectric generator.

3. The private electric generator of claim 1, wherein a size of the first heat absorbing panel is 0.5 to 1 times a size of the second heat absorbing panel.

4. The private electric generator of claim 1, wherein the first and second heat absorbing panels are a heat sink.

5. The private electric generator of claim 1, wherein at least one of the first and second heat absorbing panels includes:
a main absorbing panel; and
at least one sub-absorbing protrusion that protrudes from the main absorbing panel.

6. The private electric generator of claim 1, wherein the thermoelectric generator generates the power when the temperature difference in the heat absorbed in the first and second heat absorbing panels ranges from 5° C. to 20° C.

7. A private electric generator, comprising:
a barrier curtain that shields an external heat source;
a third heat absorbing panel that is disposed to be spaced under the barrier curtain and absorbs heat corresponding to temperature below the barrier curtain;
a fourth heat absorbing panel that absorbs heat corresponding to ground temperature or water temperature; and
a thermoelectric generator that is disposed between the third and fourth heat absorbing panels and uses a temperature difference in the heat absorbed in the third and fourth heat absorbing panels to generate power.

8. The private electric generator of claim 7, wherein a size of the third heat absorbing panel is 1 to 4 times a size of the fourth heat absorbing panel.
